(19) United States
(12) Patent Application Publication
(10) Pub. No.: US 2026/0188357 A1
(43) Pub. Date: Jul. 2, 2026

(54) MEMORY DEVICES

(71) Applicant: SAMSUNG ELECTRONICS CO., LTD., Suwon-si (KR)

(72) Inventors: Yuna GIL, Suwon-si (KR); Chaelyoung KIM, Suwon-si (KR)

(73) Assignee: SAMSUNG ELECTRONICS CO., LTD., Suwon-si (KR)

(21) Appl. No.: 19/295,276

(22) Filed: Aug. 8, 2025

(30) Foreign Application Priority Data
Dec. 26, 2024 (KR) 10-2024-0197209

(51) Int. Cl. G11C 5/06; H10B 63/00; H10N 70/00

(52) U.S. Cl. CPC G11C 5/063; H10B 63/24; H10B 63/84; H10N 70/841

(57) ABSTRACT

A memory device includes a first conductive line on a substrate and extending in a first direction substantially parallel to an upper surface of the substrate; a second conductive line over the first conductive line and extending in a second direction that is substantially parallel to the upper surface of the substrate and intersects the first direction; and a memory cell including a first electrode, a selection pattern including an Ovonic Threshold Switch (OTS) material, and a second electrode sequentially stacked between an upper surface of the first conductive line and a lower surface of the second conductive line. A barrier structure covers an upper surface, a lower surface, and opposite sidewalls in the first and second directions of the selection pattern.

### CROSS-REFERENCE TO RELATED APPLICATION

This application claims priority under 35 U.S.C. § 119 to Korean Patent Application No. 10-2024-0197209, filed on Dec. 26, 2024 with the Korean Intellectual Property Office (KIPO), the disclosure of which is incorporated by reference herein in its entirety.

### TECHNICAL FIELD

Example embodiments of the inventive concept relate to a memory device.

### DISCUSSION OF RELATED ART

As the information age has arrived, there is an increasing demand for high-performance and low-power electronic devices. Especially in the CXL (Compute eXpress Link) interface environment for efficiently using CPU, GPU, AI accelerators, memory, etc., the need for new memory solutions that can optimize performance and capacity is emerging.

In response to these demands, Selector Only Memory (SOM) is gaining attention. SOM has a single cell structure consisting of OTS (Ovonic Threshold Switch) material between two electrodes, which is a new type of memory device that implements the dual structure of resistance change material and selector device used in conventional phase-change memory (PRAM) as a single device.

SOM stores data by using the threshold voltage change according to the polarity relationship between Write and Read operations. When Write and Read have the same polarity direction (Positive-Positive, PP), it becomes a Low Threshold State (LTS), resulting in a SET state, and when Write and Read have opposite polarity directions (Negative-Positive, NP), it becomes a High Threshold State (HTS), resulting in a RESET state.

However, as SET/RESET Write operations are repeated in SOM, durability degradation may occur due to the loss of OTS components, for example, selenium anions. In particular, changes in the composition of OTS can alter the threshold voltage characteristics of the selector device, hindering stable cell operation. Therefore, to commercialize SOM, it is necessary to solve the technical challenge of improving durability for SET/RESET Write operations.

### SUMMARY

Example embodiments of the inventive concept provide a memory device having enhanced electrical characteristics.

According to example embodiments of the inventive concept, there is provided a memory device. The memory device may include a first conductive line on a substrate and extending in a first direction substantially parallel to an upper surface of the substrate; a second conductive line on the first conductive line and extending in a second direction that is substantially parallel to the upper surface of the substrate and crosses the first direction; a memory cell including a first electrode, a selection pattern including an Ovonic Threshold Switch (OTS) material, and a second electrode that are sequentially stacked between an upper surface of the first conductive line and a lower surface of the second conductive line; and a barrier structure covering an upper surface, a lower surface, opposite sidewalls in the first direction and opposite sidewalls in the second direction of the selection pattern.

According to example embodiments of the inventive concept, there is provided a memory device. The memory device may include a first conductive line on a substrate and extending in a first direction substantially parallel to an upper surface of the substrate; a second conductive line on the first conductive line and extending in a second direction that is substantially parallel to the upper surface of the substrate and crosses the first direction; a first electrode on an upper surface of the first conductive line in a region where the first and second conductive lines overlap each other in a third direction substantially perpendicular to the upper surface of the substrate; a first barrier pattern on the first electrode and including silicon nitride or a high-k dielectric material; a selection pattern on the first barrier pattern; a second barrier pattern on the selection pattern and including silicon nitride or a high-k dielectric material; a second electrode on the second barrier pattern; third barrier patterns respectively covering opposite sidewalls in the second direction of the selection pattern; and barrier lines respectively covering opposite sidewalls in the first direction of the selection pattern.

According to example embodiments of the inventive concept, there is provided a memory device. The memory device may include first conductive lines disposed on a substrate, each extending in a first direction substantially parallel to an upper surface of the substrate, and spaced apart from each other in a second direction that is substantially parallel to the upper surface of the substrate and crosses the first direction; second conductive lines disposed on the first conductive lines, each extending in the second direction, and spaced apart from each other in the first direction; first electrodes disposed on upper surfaces of the first conductive lines in regions where the first and second conductive lines overlap each other in a third direction substantially perpendicular to the upper surface of the substrate, respectively; stack structures disposed on the first electrodes, respectively, each of the stack structures including a first barrier pattern, a selection pattern disposed on the first barrier pattern, a second barrier pattern disposed on the selection pattern, and a second electrode disposed on the second barrier pattern; third barrier patterns covering sidewalls in the second direction of the stack structures; and barrier lines extending in the second direction and covering sidewalls in the first direction of the stack structures disposed along the second direction, wherein each of the third barrier patterns covers an edge portion in the second direction of an upper surface of each of the first electrodes, and each of the barrier lines covers edge portions in the first direction of upper surfaces of the first electrodes disposed along the second direction.

In the memory device according to example embodiments, as SET/RESET Write operations are repeated, escape of components from the selection patterns of each memory cell can be prevented. Accordingly, the reliability of the memory device can be improved.

### BRIEF DESCRIPTION OF THE DRAWINGS

FIGS. 1 to 4 are a perspective view, vertical cross-sectional views, and a horizontal cross-sectional view illustrating a memory device in accordance with example embodiments.

FIGS. 5 to 34 are perspective views, vertical cross-sectional views and a horizontal cross-sectional view illustrating a method of manufacturing a memory device in accordance with example embodiments.

FIGS. 35 to 38 are a perspective view, vertical cross-sectional views, and a horizontal cross-sectional view illustrating a memory device in accordance with example embodiments.

FIGS. 39 and 40 are vertical cross-sectional views illustrating a method of manufacturing a memory device in accordance with example embodiments.

### DETAILED DESCRIPTION OF THE EMBODIMENTS

The above and other aspects and features of the memory devices and the methods of manufacturing the same in accordance with example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Two directions among horizontal directions that are substantially parallel to an upper surface of the substrate, which intersect each other, may be referred to as first and second directions D1 and D2, respectively, and a direction substantially vertical to the upper surface of the substrate may be referred to as a third direction D3. In example embodiments, the first and second directions D1 and D2 may be substantially perpendicular to each other. Each of the first to third directions D1, D2 and D3 may include not only a direction shown in the drawings but also a direction opposite thereto.

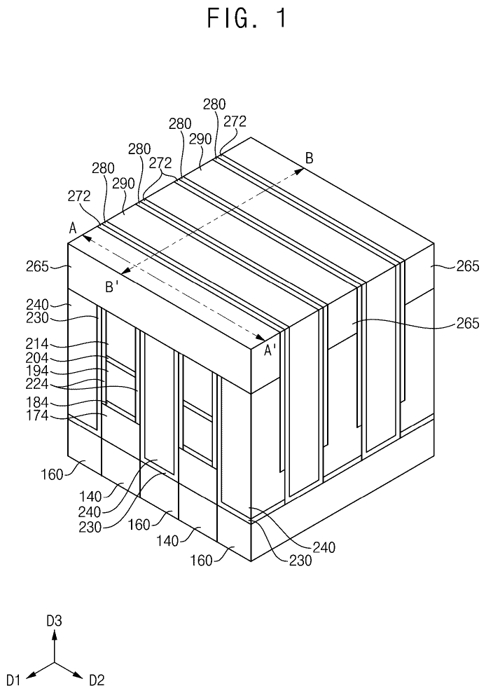

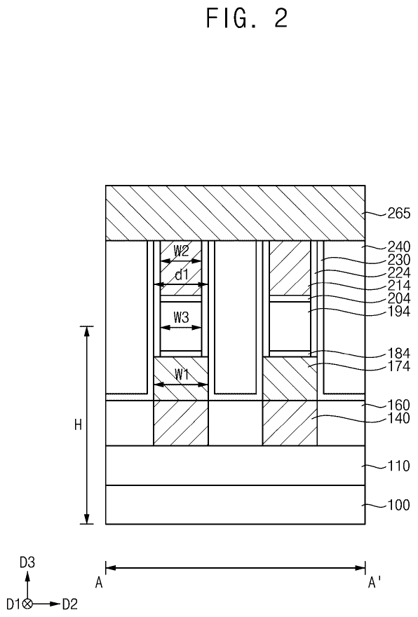

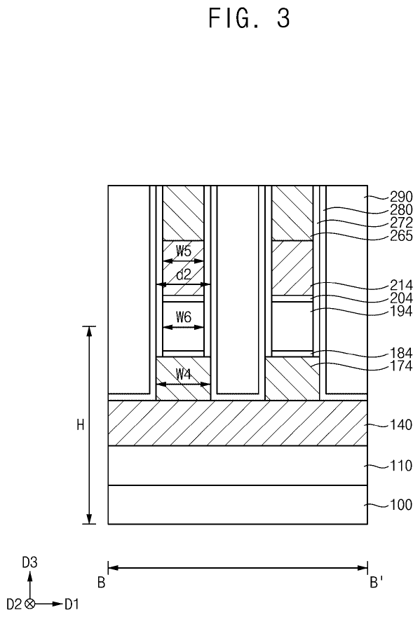

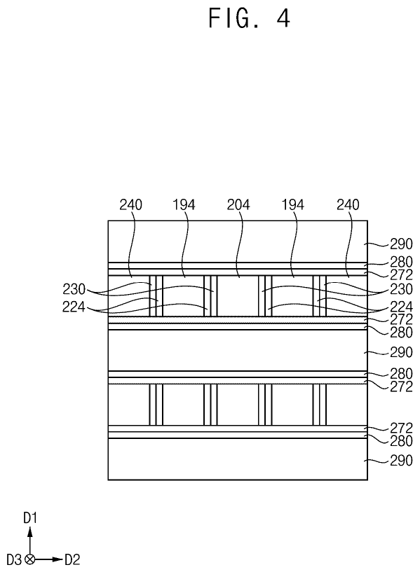

FIGS. 1 to 4 are a perspective view, vertical cross-sectional views, and a horizontal cross-sectional view illustrating a memory device in accordance with example embodiments. Particularly, FIG. 1 is a perspective view of FIGS. 2 to 4. FIG. 2 is a vertical cross-sectional view taken along line A-A′. FIG. 3 is a vertical cross-sectional view taken along line B-B′. FIG. 4 is a horizontal cross-sectional view at a height H of FIGS. 2 and 3.

Referring to FIGS. 1 to 4, the memory device may include first conductive lines 140, second conductive lines 265, memory cells, and a barrier structure on a substrate 100.

Additionally, the memory device may further include first and second insulating interlayers 110 and 160 and first and second filling structures.

The substrate 100 may include a semiconductor material, e.g., silicon, germanium, silicon-germanium, etc., or a III-V group compound semiconductor, such as GaP, GaAs, GaSb, etc. In an example embodiment, the substrate 100 may be a silicon-on-insulator (SOI) substrate or a germanium-on-insulator (GOI) substrate.

Various devices such as gate structures, source/drain layers, contact plugs, vias, wirings, etc. may be disposed on the substrate 100, and these may be covered by the first insulating interlayer 110. The first insulating interlayer 110 may include an oxide, for example, silicon oxide.

In example embodiments, the first conductive lines 140 may extend in the first direction D1 and may be spaced apart from each other in the second direction D2 on the substrate 100. Sidewalls in the second direction D2 of the first conductive lines 140 may be covered by the second insulating interlayer 160. The second insulating interlayer 160 may include an oxide, for example, silicon oxide.

In example embodiments, the second conductive lines 265 may extend in the second direction D2 and may be spaced apart from each other in the first direction D1 on the first conductive lines 140.

Each of the first and second conductive lines 140 and 265 may include a metal, for example, tungsten (W), platinum (Pt), palladium (Pd), rhodium (Rh), ruthenium (Ru), iridium (Ir), copper (Cu), aluminum (Al), titanium (Ti), tantalum (Ta), etc., or a metal nitride, for example, titanium nitride (TiNₓ), tungsten nitride (WNₓ), tantalum nitride (TaNₓ), etc.

In an example embodiment, each of the first and second conductive lines 140 and 265 may include a metal pattern and a barrier pattern covering a lower surface of the metal pattern. The metal pattern may include a metal, for example, tungsten (W), platinum (Pt), palladium (Pd), rhodium (Rh), ruthenium (Ru), iridium (Ir), copper (Cu), aluminum (Al), titanium (Ti), tantalum (Ta), etc., and the barrier pattern may include a metal nitride, for example, titanium nitride (TiNₓ), tungsten nitride (WNₓ), tantalum nitride (TaNₓ), etc.

Each of the first conductive lines 140 may serve as word lines, and each of the second conductive lines 265 may serve as bit lines. Alternatively, each of the first conductive lines 140 may serve as bit lines, and each of the second conductive lines 265 may serve as word lines.

In the following description, it is assumed that each of the first conductive lines 140 serves as word lines, and each of the second conductive lines 265 serves as bit lines.

The memory cells may be disposed in regions where the first and second conductive lines 140 and 265 overlap in the third direction D3. Accordingly, the memory cells may be spaced apart from each other in the first and second directions D1 and D2, forming a memory cell array. In example embodiments, the memory cells included in the memory cell array may be arranged in a grid pattern in a plan view.

Each of the memory cells may include a first electrode 174, a selection pattern 194, and a second electrode 214 sequentially stacked in the third direction D3 on an upper surface of a first conductive line 140. Accordingly, a plurality of first electrodes 174 may be spaced apart from each other in the first and second directions D1 and D2, a plurality of selection patterns 194 may be spaced apart from each other in the first and second directions D1 and D2, and a plurality of second electrodes 214 may be spaced apart from each other in the first and second directions D1 and D2.

In example embodiments, the first electrodes 174 may include carbon-based materials or carbon compounds such as amorphous carbon (a-C), conductive carbon (C), graphite, graphene, carbon nitride (CN), tungsten carbon nitride (WCN), tungsten doped carbon (W doped C), molybdenum doped carbon (Mo doped W), etc.

In example embodiments, the first electrodes 174 may include a metal, for example, tungsten (W), molybdenum (Mo), tantalum (Ta), titanium (Ti), scandium (Sc), nickel (Ni), vanadium (V), niobium (Nb), chromium (Cr), zirconium (Zr), hafnium (Hf), etc., a metal nitride, for example, titanium nitride (TiNₓ), tungsten nitride (WNₓ), tantalum nitride (TaNₓ), etc., or a metal silicon nitride, for example, titanium silicon nitride (TiSiNₓ), tungsten silicon nitride (WSiNₓ), tantalum silicon nitride (TaSiNₓ), zirconium silicon nitride (ZrSiNₓ), etc.

Each of the first electrodes 174 may be referred to as a lower electrode of the memory device and may have a multilayer structure consisting of two or more layers.

In example embodiments, the selection patterns 194 may include a chalcogenide material. The chalcogenide material may include at least one chalcogen element selected from a group including sulfur(S), selenium (Se), and tellurium (Te), which are group 16 elements, and at least one element selected from a group including germanium (Ge), which is a group 14 element, and arsenic (As) and antimony (Sb), which are group 15 elements.

In example embodiments, the selection patterns 194 may include a chalcogenide material containing selenium (Se).

In example embodiments, the selection patterns 194 may include a Ovonic Threshold Switch (OTS) material. The OTS material is a material that exhibits threshold switching characteristics among chalcogenide materials.

In example embodiments, the selection patterns 194 may include an OTS material containing selenium (Se). The OTS material containing selenium (Se) may include As—Se-based, Ge—As—Se-based, Sb—Se-based, etc., and may be implemented with various composition ratios according to operational characteristics of the memory device including the selection patterns 194.

In example embodiments, the second electrodes 214 may include carbon-based materials or carbon compounds such as conductive carbon (C), graphite, graphene, carbon nitride (CN), tungsten carbon nitride (WCN), tungsten doped carbon (W doped C), molybdenum doped carbon (Mo doped W), etc.

In example embodiments, the second electrodes 214 may include a metal, for example, tungsten (W), molybdenum (Mo), tantalum (Ta), titanium (Ti), scandium (Sc), nickel (Ni), vanadium (V), niobium (Nb), chromium (Cr), zirconium (Zr), hafnium (Hf), etc., a metal nitride, for example, titanium nitride (TiNₓ), tungsten nitride (WNₓ), tantalum nitride (TaNₓ), etc., or a metal silicon nitride, for example, titanium silicon nitride (TiSiNₓ), tungsten silicon nitride (WSiNₓ), tantalum silicon nitride (TaSiNₓ), zirconium silicon nitride (ZrSiNₓ), etc.

Each of the second electrodes 214 may be referred to as an upper electrode of the memory device and may have a multilayer structure consisting of two or more layers.

In example embodiments, a first width W1 in the second direction D2 of the first electrode 174 may be greater than a second width W2 in the second direction D2 of the second electrode 214. In example embodiments, a third width W3 in the second direction D2 of the selection pattern 194 may be substantially the same as the second width W2 in the second direction D2 of the second electrode 214.

In example embodiments, a fourth width W4 in the first direction D1 of the first electrode 174 may be greater than a fifth width W5 in the first direction D1 of the second electrode 214. In example embodiments, a sixth width W6 in the first direction D1 of the selection pattern 194 may be substantially the same as the fifth width W5 in the first direction D1 of the second electrode 214.

In example embodiments, a first area of a horizontal cross-section of the first electrode 174 may be greater than a second area of a horizontal cross-section of the second electrode 214. In example embodiments, a third area of a horizontal cross-section of the selection pattern 194 may be substantially the same as the second area of the horizontal cross-section of the second electrode 214.

The barrier structure may cover an upper surface, a lower surface, opposite sidewalls in the first direction D1, and opposite sidewalls in the second direction D2 of the selection pattern 194 included in each of the memory cells. That is, the barrier structure may surround the selection pattern 194.

In example embodiments, the barrier structure may include first barrier patterns 184, second barrier patterns 204, third barrier patterns 224 and fourth barrier lines 272.

Each of the first barrier patterns 184 may be interposed between the first electrode 174 and the selection pattern 194 stacked in the third direction D3 and may cover a lower surface of the selection pattern 194.

Each of the second barrier patterns 204 may be interposed between the selection pattern 194 and the second electrode 214 stacked in the third direction D3 and may cover an upper surface of the selection pattern 194.

That is, a first barrier pattern 184 may be interposed between the first electrode 174 and the selection pattern 194, and a second barrier pattern 204 may be interposed between the selection pattern 194 and the second electrode 214. Accordingly, the first electrode 174, the first barrier pattern 184, the selection pattern 194, the second barrier pattern 204, and the second electrode 214 may be sequentially stacked in the third direction D3 on the upper surface of the first conductive line 140.

For convenience of explanation, the first barrier pattern 184, the selection pattern 194, the second barrier pattern 204, and the second electrode 214 sequentially stacked on the first electrode 174 will be collectively referred to as a stack structure. Accordingly, the stack structures may be spaced apart from each other in the first and second directions D1 and D2.

Each of the third barrier patterns 224 may cover a sidewall in the second direction D2 of the selection pattern 194. In example embodiments, the opposite sidewalls in the second direction D2 of the selection pattern 194 may be covered by the third barrier patterns 224. In example embodiments, each of the third barrier patterns 224 may cover an edge portion in the second direction D2 of an upper surface of the first electrode 174 and a sidewall in the second direction D2 of the stack structure.

In example embodiments, the third barrier patterns 224 may be disposed on sidewalls in the second direction D2 of the selection patterns 194, respectively, and may be spaced apart from each other in the first and second directions D1 and D2.

Each of the fourth barrier lines 272 may cover a sidewall in the first direction D1 of the selection pattern 194. In example embodiments, the opposite sidewalls in the first direction D1 of the selection pattern 194 may be covered by the fourth barrier lines 272. In example embodiments, each of the fourth barrier lines 272 may cover edge portions in the first direction D1 of upper surfaces of the first electrodes 174 disposed along the second direction D2, sidewalls in the first direction D1 of the stack structures disposed along the second direction D2, and a sidewall in the first direction D1 of a second conductive line 265. In example embodiments, each of the fourth barrier lines 272 may also cover sidewalls in the first direction D1 of the third barrier patterns 224, a sidewall in the first direction D1 of the first protection layer 230, and a sidewall in the first direction D1 of the first filling layer 240.

In example embodiments, the fourth barrier lines 272 may extend in the second direction D2 along the sidewalls in the first direction D1 of the stack structures disposed along the second direction D2, and may be spaced apart from each other in the first direction D1.

In example embodiments, as the third barrier patterns 224 cover edge portions in the second direction D2 of the upper surfaces of the first electrodes 174, sidewalls in the second direction D2 of the first electrodes 174 and the sidewalls in the second direction D2 of the selection patterns 194 may be spaced apart from each other in the second direction D2. In example embodiments, as the fourth barrier lines 272 cover edge portions in the first direction D1 of the upper surfaces of the first electrodes 174, sidewalls in the first direction D1 of the first electrodes 174 and the sidewalls in the first direction D1 of the selection patterns 194 may be spaced apart from each other in the first direction D1.

In example embodiments, a first distance d1 between outer sidewalls of the third barrier patterns 224 disposed on opposite sidewalls in the second direction D2 of each of the stack structures may be substantially the same as the first width W1 of the first electrode 174.

In example embodiments, a second distance d2 between outer sidewalls of the fourth barrier lines 272 disposed on opposite sidewalls in the first direction D1 of each of the stack structures may be substantially the same as the fourth width W4 of the first electrode 174.

In example embodiments, each of the first to third barrier patterns 184, 204 and 224 and the fourth barrier lines 272 may include silicon nitride (SiN). In example embodiments, when each of the first to third barrier patterns 184, 204 and 224 and the fourth barrier lines 272 is a silicon nitride layer, thickness of the silicon nitride layer may range from about 10 Å to 20 Å. If the thickness of the silicon nitride layer is less than 10 Å, it may be difficult to sufficiently prevent escape of components of the selection patterns 194, and if the thickness of the silicon nitride layer is greater than 20 Å, the memory device may not operate.

In example embodiments, each of the first to third barrier patterns 184, 204 and 224 and the fourth barrier lines 272 may include a high-k dielectric material, for example, hafnium oxide (HfO₂), zirconium oxide (ZrO₂), aluminum oxide (Al₂O₃), tantalum oxide (Ta₂O₅), titanium oxide (TiO₂), etc. In the present invention, a high-k dielectric material refers to a material having a higher dielectric constant than silicon oxide (SiO₂) (k≈3.9). In example embodiments, when each of the first to third barrier patterns 184, 204 and 224 and the fourth barrier lines 272 is a high-k dielectric material layer, thickness of the high-k dielectric material layer may be set within a range that allows normal operation of the memory device.

In example embodiments, each of the first to third barrier patterns 184, 204 and 224 and the fourth barrier lines 272 may be a cation exchange membrane. The cation exchange membrane may be formed of fluorine-based polymers including Perfluorosulfonic acid (PFSA) series, or hydrocarbon-based polymers including sulfonated polyetheretherketone (SPEEK), sulfonated polysulfone (SPSF), sulfonated polyimide (SPI), etc.

In example embodiments, the first to third barrier patterns 184, 204 and 224 and the fourth barrier lines 272 may include substantially the same material or may include different materials from each other.

The first filling structure may fill space between the memory cells neighboring in the second direction D2. In example embodiments, the first filling structure may include a first protection layer 230 and a first filling layer 240.

The first protection layer 230 may cover outer sidewalls in the second direction D2 of the third barrier patterns 224, sidewalls in the second direction D2 of the first electrodes 174, and an upper surface of the second insulating interlayer 160. In example embodiments, the first protection layer 230 may include a plurality of portions spaced apart from each other in the first and second directions D1 and D2.

The first protection layer 230 may include an insulating nitride, for example, silicon nitride.

The first filling layer 240 may be disposed on the first protection layer 230 to fill a remaining space between the memory cells neighboring in the second direction D2. In example embodiments, the first filling layer 240 may include a plurality of portions spaced apart from each other in the first and second directions D1 and D2, corresponding to the first protection layer 230.

The first filling layer 240 may include, for example, silicon oxycarbide, silicon oxide, etc.

In example embodiments, a lower surface of the first filling structure may be lower than lower surfaces of the third barrier patterns 224.

The second filling structure may fill a space between the memory cells neighboring in the first direction D1. In example embodiments, the second filling structure may include a second protection layer 280 and a second filling layer 290.

The second protection layer 280 may cover outer sidewalls in the first direction D1 of the fourth barrier lines 272, the sidewalls in the first direction D1 of the first electrodes 174, sidewalls in the first direction D1 of the first protection layer 230, sidewalls in the first direction D1 of the first filling layer 240, upper surfaces of the first conductive lines 140, and the upper surface of the second insulating interlayer 160. In example embodiments, the second protection layer 280 may include a plurality of portions extending in the second direction D2 and spaced apart from each other in the first direction D1.

The second protection layer 280 may include an insulating nitride, for example, silicon nitride.

The second filling layer 290 may be disposed on the second protection layer 280 to fill a remaining space between the memory cells neighboring in the first direction D1. In example embodiments, the second filling layer 290 may include a plurality of portions extending in the second direction D2 and spaced apart from each other in the first direction D1, corresponding to the second protection layer 280.

The second filling layer 290 may include, for example, silicon oxycarbide, silicon oxide, etc.

In example embodiments, a lower surface of the second filling structure may be lower than lower surfaces of the fourth barrier lines 272.

In the memory device, as the SET/RESET Write cycle is repeated, components of the selection pattern 194, for example, selenium anions (Se⁻), may migrate and/or escape toward the upper electrode or the lower electrode, causing endurance failure.

However, according to example embodiments, the memory device may include the barrier structure covering the upper and lower surfaces and the sidewalls of the selection pattern 194. Accordingly, migration or the escape of the components from the selection pattern 194 through the upper and lower surfaces or the sidewalls of the selection pattern 194 may be reduced and/or prevented, thereby improving reliability of the memory device.

Meanwhile, the components of the selection pattern 194 may migrate and/or escape along the sidewalls of the selection pattern 194 and the first electrode 174.

However, in the memory device according to example embodiments, the edge portions of the upper surface of the first electrode 174 may be covered by the third barrier patterns 224 and the fourth barrier lines 272 of the barrier structure. Accordingly, the sidewalls of the first electrode 174 may be spaced apart from the sidewalls of the selection pattern 194 in the horizontal direction, which may prevent and/or reduce the components of the selection pattern 194 from migrating and/or escaping along the sidewalls of the selection pattern 194 and the first electrode 174, thereby improving the reliability of the memory device.

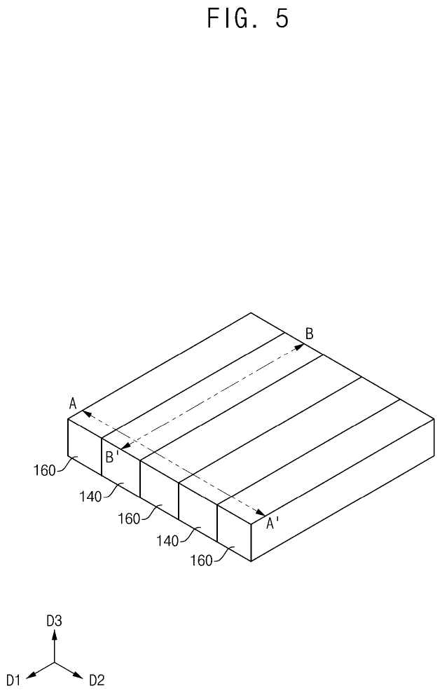

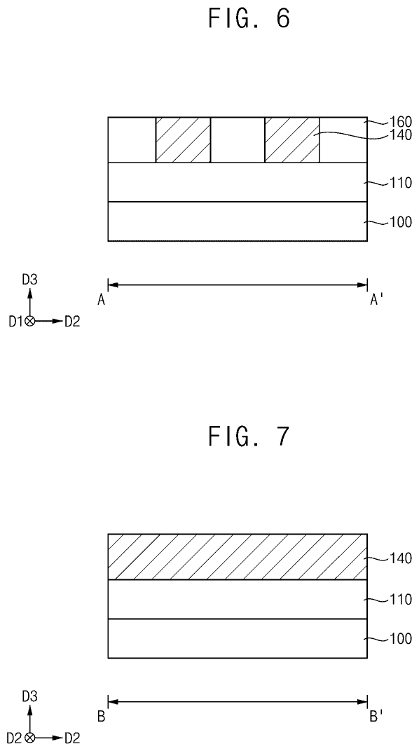

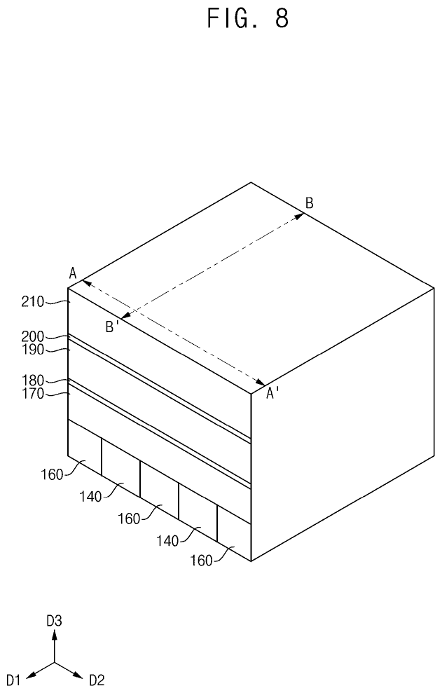

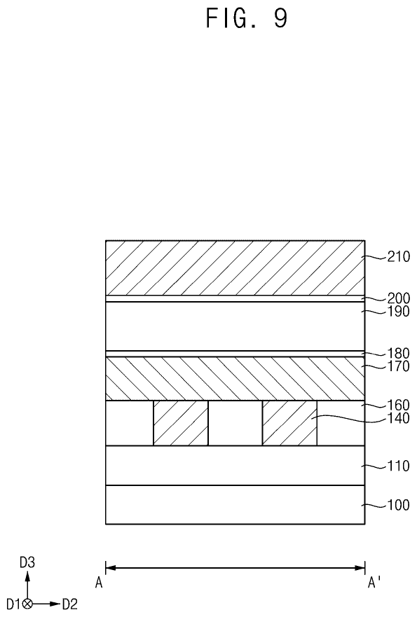

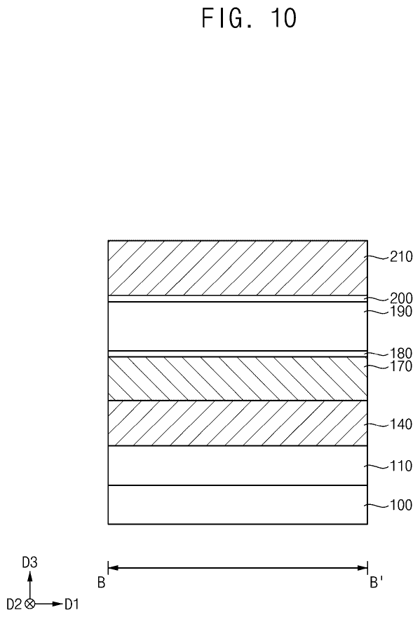

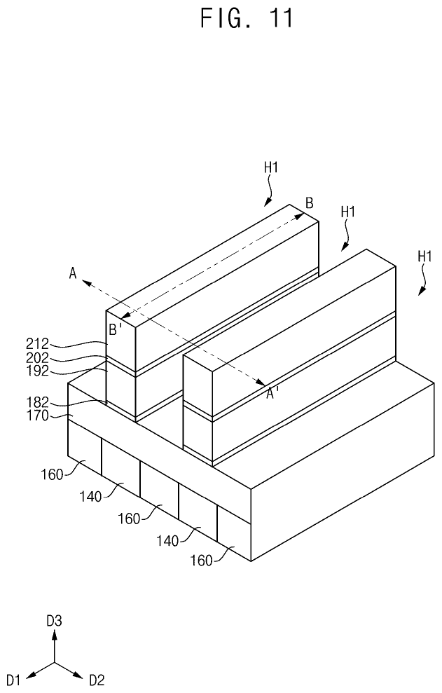

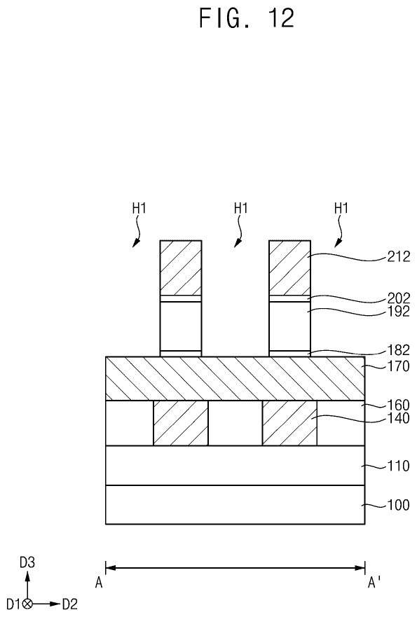

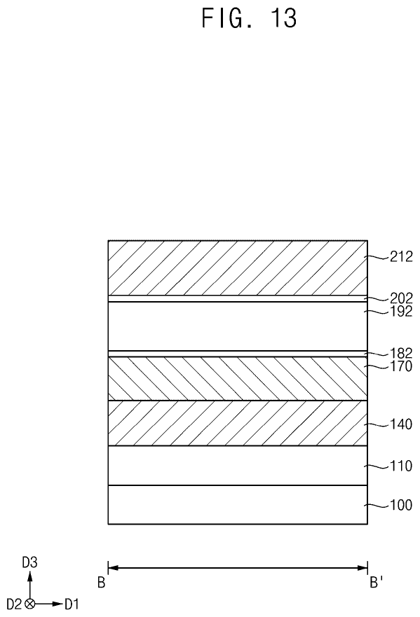

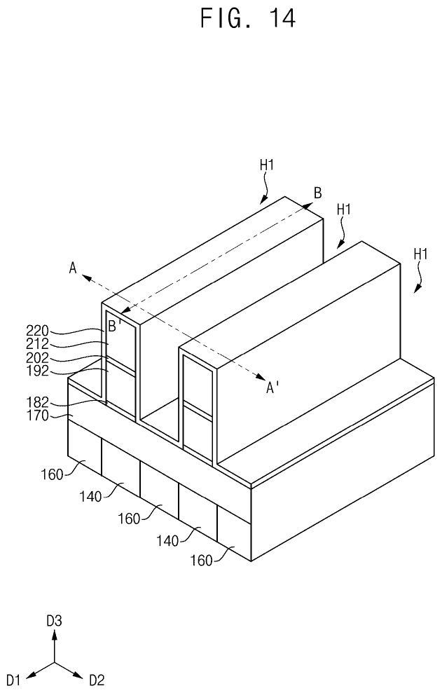

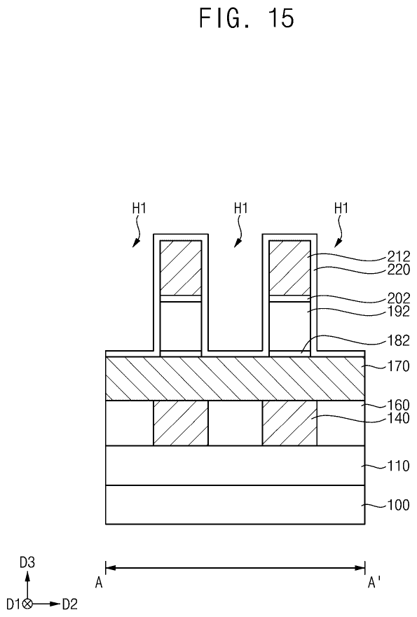

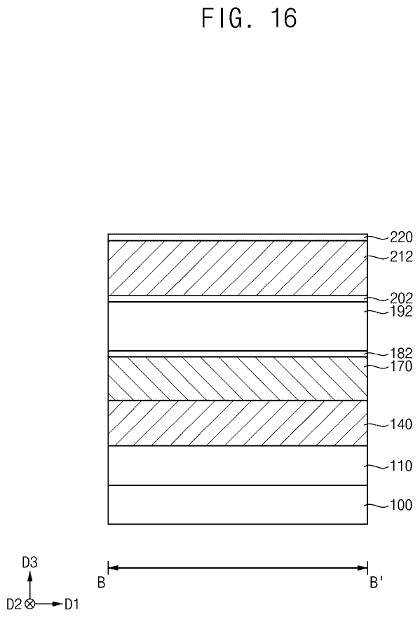

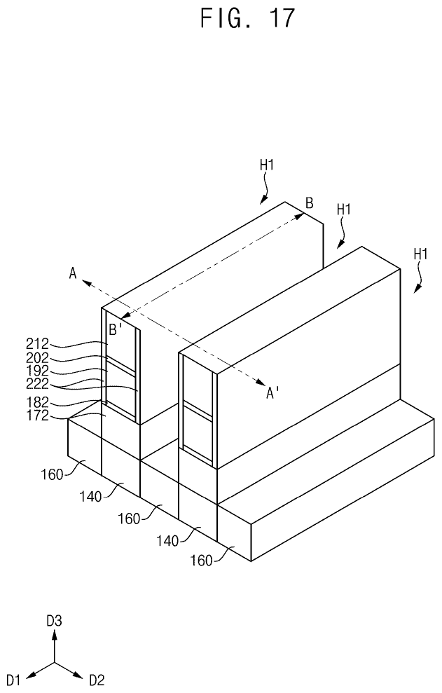

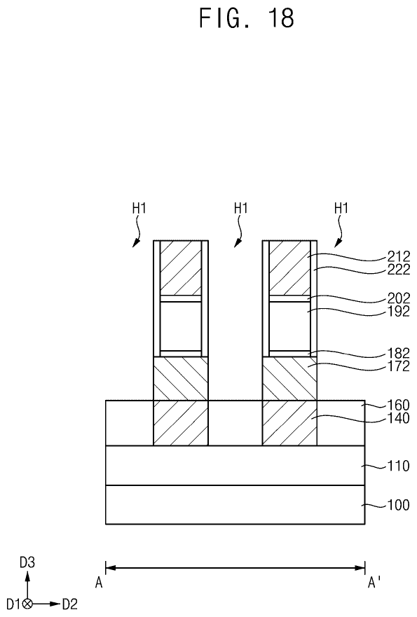

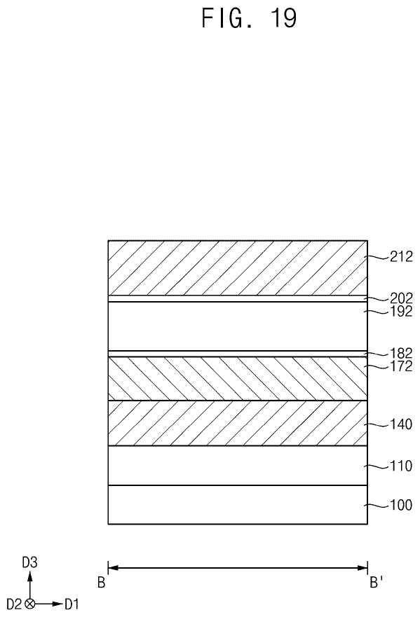

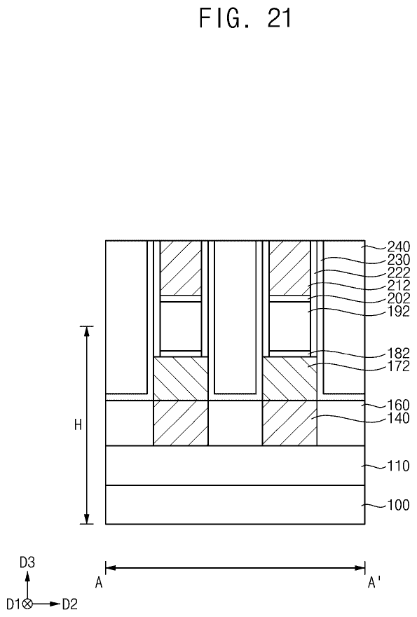

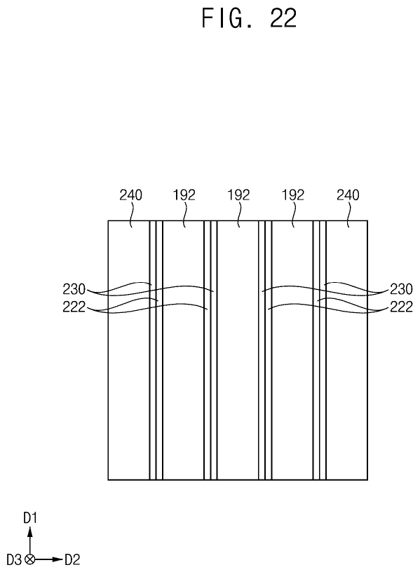

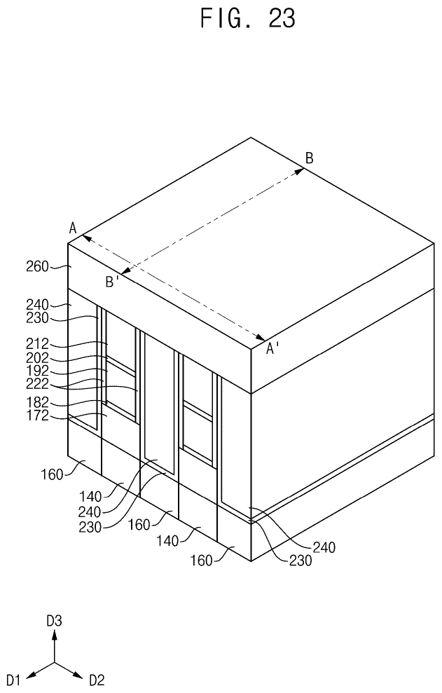

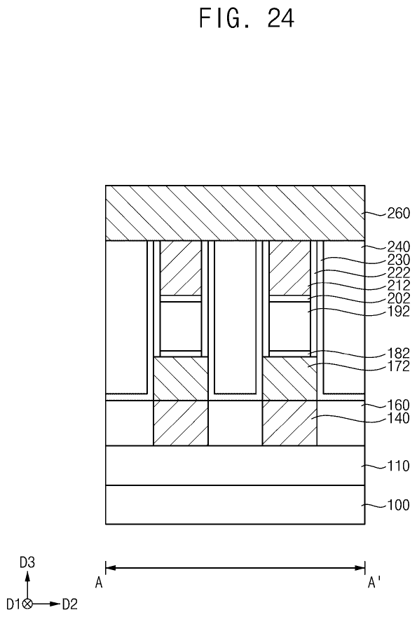

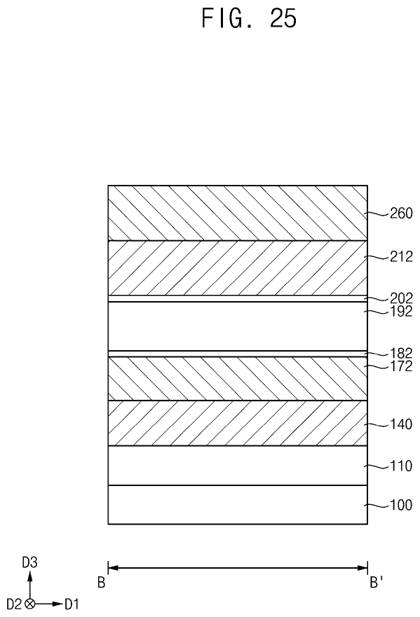

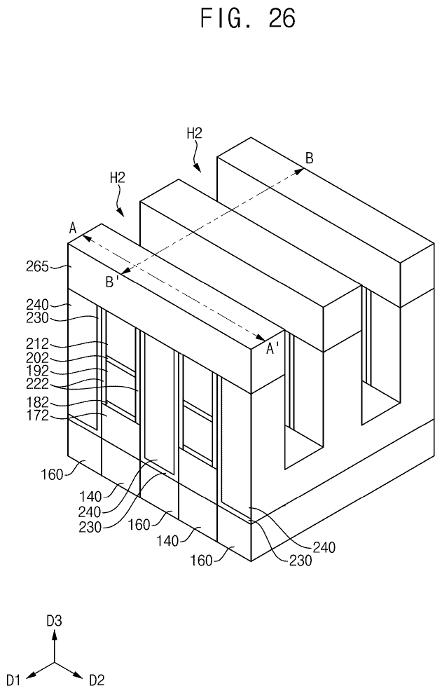

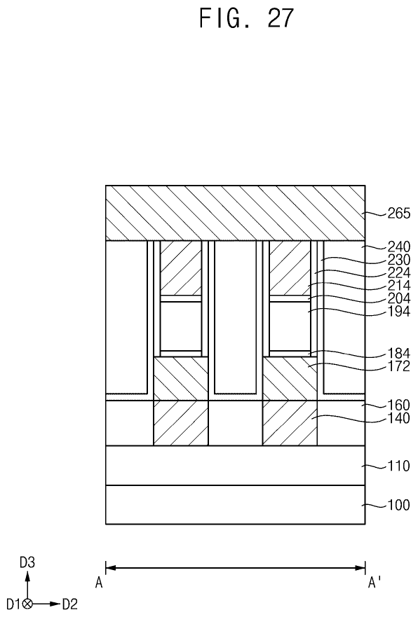

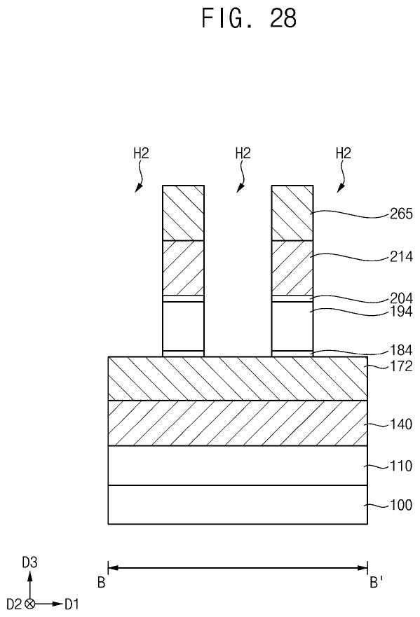

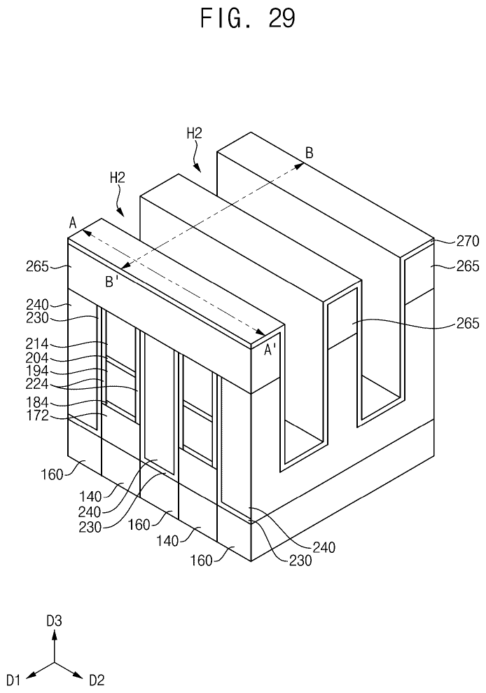

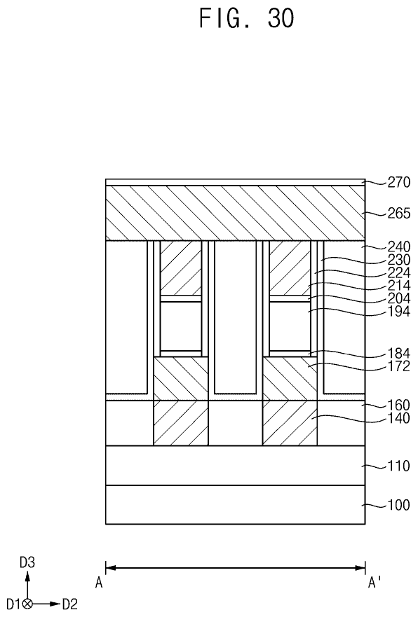

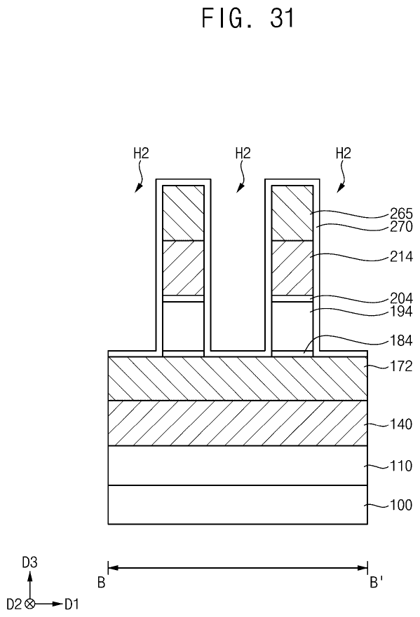

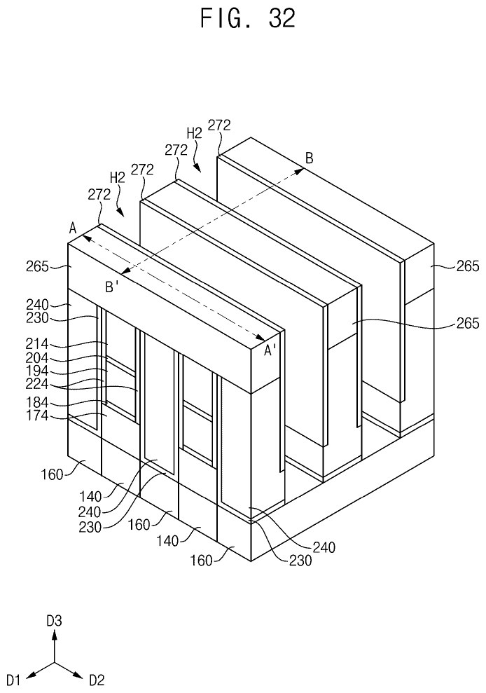

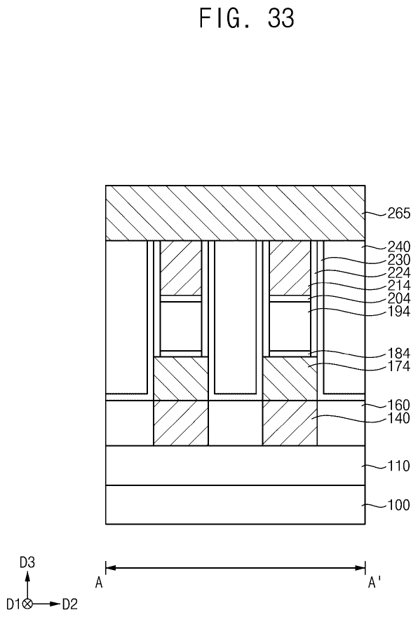

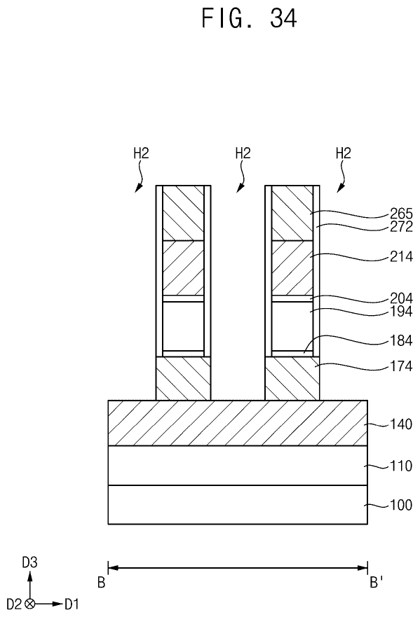

FIGS. 5 to 34 are perspective views, vertical cross-sectional views, and a horizontal cross-sectional view illustrating a method of manufacturing a memory device in accordance with example embodiments. Specifically, FIGS. 5, 8, 11, 14, 17, 20, 23, 26, 29, and 32 are perspective views. FIGS. 6, 9, 12, 15, 18, 21, 24, 27, 30, and 33 are vertical cross-sectional views taken along lines A-A′ of corresponding perspective views. FIGS. 7, 10, 13, 16, 19, 25, 28, 31, and 34 are vertical cross-sectional views taken along lines B-B′ of corresponding perspective views. FIG. 22 is a horizontal cross-sectional view at a height H of FIG. 21.

Referring to FIGS. 5 to 7, a first insulating interlayer 110 may be formed on a substrate 100.

Various devices such as gate structures, source/drain layers, contact plugs, vias, wirings, etc. may be formed on the substrate 100, and these may be covered by the first insulating interlayer 110. The first insulating interlayer 110 may an oxide include, for example, silicon oxide.

Subsequently, a first conductive layer may be formed on the first insulating interlayer 110.

The first conductive layer may include a metal, for example, tungsten (W), platinum (Pt), palladium (Pd), rhodium (Rh), ruthenium (Ru), iridium (Ir), copper (Cu), aluminum (Al), titanium (Ti), tantalum (Ta), etc., or a metal nitride, for example, titanium nitride (TiNₓ), tungsten nitride (WNₓ), tantalum nitride (TaNₓ), etc.

In an example embodiment, the first conductive layer may include a metal layer and a barrier layer covering a lower surface of the metal layer. The metal layer may include a metal, for example, tungsten (W), platinum (Pt), palladium (Pd), rhodium (Rh), ruthenium (Ru), iridium (Ir), copper (Cu), aluminum (Al), titanium (Ti), tantalum (Ta), etc., and the barrier layer may include a metal nitride, for example, titanium nitride (TiNx), tungsten nitride (WNx), tantalum nitride (TaNx), etc.

An etching process may be performed on the first conductive layer to form first conductive lines 140. In example embodiments, the first conductive lines 140 may be formed to extend in the first direction D1 and may be spaced apart from each other in the second direction D2.

Subsequently, a second insulating interlayer 160 may be formed on the first conductive lines 140, and a planarization process may be performed on an upper portion of the second insulating interlayer 160 until upper surfaces of the first conductive lines 140 are exposed. Accordingly, the second insulating interlayer 160 may be separated into a plurality of portions extending in the first direction D1 and may be spaced apart from each other along the second direction D2 between the first conductive lines 140.

The planarization process may be performed, for example, by a chemical mechanical polishing (CMP) process and/or an etch-back process.

Referring to FIGS. 8 to 10, a first electrode layer 170, a first barrier layer 180, a selection layer 190, a second barrier layer 200, and a second electrode layer 210 may be sequentially formed on the first conductive lines 140 and the second insulating interlayer 160.

In example embodiments, each of the first and second electrode layers 170 and 210 may include carbon-based materials or carbon compounds such as amorphous carbon (a-C), conductive carbon (C), graphite, graphene, carbon nitride (CN), tungsten carbon nitride (WCN), tungsten doped carbon (W doped C), molybdenum doped carbon (Mo doped W), etc. Alternatively, each of the first and second electrode layers 170 and 210 may include a metal, for example, tungsten (W), molybdenum (Mo), tantalum (Ta), titanium (Ti), scandium (Sc), nickel (Ni), vanadium (V), niobium (Nb), chromium (Cr), zirconium (Zr), hafnium (Hf), etc., a metal nitride, for example, titanium nitride (TiNₓ), tungsten nitride (WNₓ), tantalum nitride (TaNₓ), etc., or a metal silicon nitride, for example, titanium silicon nitride (TiSiNₓ), tungsten silicon nitride (WSiNₓ), tantalum silicon nitride (TaSiNₓ), zirconium silicon nitride (ZrSiNₓ), etc.

In example embodiments, each of the first and second barrier layers 180 and 200 may include silicon nitride (SiN). In example embodiments, when each of the first and second barrier layers 180 and 200 is a silicon nitride layer, a thickness of the silicon nitride layer may range from about 10 Å to 20 Å.

In example embodiments, each of the first and second barrier layers 180 and 200 may include a high-k dielectric material, for example, such as hafnium oxide (HfO₂), zirconium oxide (ZrO₂), aluminum oxide (Al₂O₃), tantalum oxide (Ta₂O₅), titanium oxide (TiO₂), etc.

In example embodiments, each of the first and second barrier layers 180 and 200 may be a cation exchange membrane. The cation exchange membrane may be formed of fluorine-based polymers including Perfluorosulfonic acid (PFSA) series, or hydrocarbon-based polymers including sulfonated polyetheretherketone (SPEEK), sulfonated polysulfone (SPSF), sulfonated polyimide (SPI), etc.

In example embodiments, the selection layer 190 may include a chalcogenide material. The chalcogenide material may be formed to include at least one chalcogen element selected from a group including sulfur(S), selenium (Se), and tellurium (Te), which are group 16 elements, and at least one element selected from a group including germanium (Ge), which is a group 14 element, and arsenic (As) and antimony (Sb), which are group 15 elements. In example embodiments, the selection layer 190 may include a chalcogenide material containing selenium (Se).

In example embodiments, the selection layer 190 may include an Ovonic Threshold Switch (OTS) material. The OTS material is a material that exhibits threshold switching characteristics among chalcogenide materials. In example embodiments, the selection layer 190 may include an OTS material containing selenium (Se). The OTS material containing selenium (Se) may include As—Se-based, Ge—As—Se-based, Sb—Se-based, etc., and may be implemented with various composition ratios according to operational characteristics of the memory device including the selection patterns 194.

Referring to FIGS. 11 to 13, an etching process may be performed on the second electrode layer 210, the second barrier layer 200, the selection layer 190, and the first barrier layer 180 to form first openings H1 exposing an upper surface of the first electrode layer 170.

In example embodiments, the first openings H1 may be formed to extend in the first direction D1 and may be spaced apart from each other in the second direction D2.

By the etching process, the second electrode layer 210, the second barrier layer 200, the selection layer 190, and the first barrier layer 180 may be separated into a plurality of second electrode lines 212, a plurality of second barrier lines 202, a plurality of selection lines 192, and a plurality of first barrier lines 182, respectively.

In example embodiments, the first barrier lines 182 may be formed to extend in the first direction D1 and may be spaced apart from each other in the second direction D2. In example embodiments, the selection lines 192 may be formed to extend in the first direction D1 and may be spaced apart from each other in the second direction D2. In example embodiments, the second barrier lines 202 may be formed to extend in the first direction D1 and may be spaced apart from each other in the second direction D2. In example embodiments, the second electrode lines 212 may be formed to extend in the first direction D1 and may be spaced apart from each other in the second direction D2.

Meanwhile, a first barrier line 182, a selection line 192, a second barrier line 202, and a second electrode line 212 sequentially stacked on the first electrode layer 170 may together form each of preliminary line structures. In example embodiments, the preliminary line structures may be formed to extend in the first direction D1 and may be spaced apart from each other in the second direction D2.

Referring to FIGS. 14 to 16, a third barrier layer 220 may be formed along upper surfaces of the preliminary line structures, opposite sidewalls in the second direction D2 of the preliminary line structures, and the upper surface of the first electrode layer 170 exposed by the first opening H1.

In example embodiments, the third barrier layer 220 may include silicon nitride (SiN). In example embodiments, when the third barrier layer 220 is a silicon nitride layer, a thickness of the silicon nitride layer may range from about 10 Å to 20 Å.

In example embodiments, the third barrier layer 220 may include a high-k dielectric material, for example, hafnium oxide (HfO₂), zirconium oxide (ZrO₂), aluminum oxide (Al₂O₃), tantalum oxide (Ta₂O₅), titanium oxide (TiO₂), etc.

In example embodiments, the third barrier layer 220 may be a cation exchange membrane. The cation exchange membrane may be formed of fluorine-based polymers including Perfluorosulfonic acid (PFSA) series, or hydrocarbon-based polymers including sulfonated polyetheretherketone (SPEEK), sulfonated polysulfone (SPSF), sulfonated polyimide (SPI), etc.

Referring to FIGS. 17 to 19, an anisotropic etching process, for example, may be performed on the third barrier layer 220. Accordingly, the third barrier layer 220 may be separated into a plurality of third barrier lines 222.

Subsequently, an etching process may be performed on the first electrode layer 170 through the first openings H1 to expose the upper surface of the second insulating interlayer 160. Accordingly, the first openings H1 may be expanded in the third direction D3.

By the etching process, the first electrode layer 170 may be separated into a plurality of first electrode lines 172. In example embodiments, the first electrode lines 172 may be formed to extend in the first direction D1 and may be spaced apart from each other in the second direction D2.

During the etching process, since the sidewalls in the second direction D2 of the preliminary line structures are covered by the third barrier lines 222, a width in the second direction D2 of each of the first electrode lines 172 may be formed larger than a width in the second direction D2 of each of the preliminary line structures.

In example embodiments, the third barrier lines 222 may be formed on the edge portions in the second direction D2 of upper surfaces of the first electrode lines 172, may be formed to extend in the first direction D1 along the sidewalls in the second direction D2 of the preliminary line structures, and may be formed to be spaced apart from each other in the second direction D2.

A preliminary line structure, the third barrier lines 222 covering opposite sidewalls in the second direction D2 of the preliminary line structure, and the first electrode line 172 thereunder may together form each of line structures. In example embodiments, the line structures may be formed to extend in the first direction D1 and may be spaced apart from each other in the second direction D2.

In example embodiments, a distance between outer sidewalls in the second direction D2 of the third barrier patterns 224 formed on opposite sidewalls in the second direction D2 of each of the line structures may be formed to be substantially the same as the width in the second direction D2 of each of the first electrode lines 172.

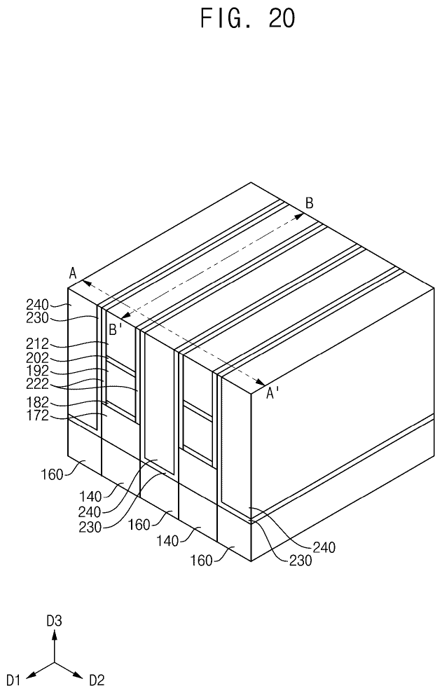

Referring to FIGS. 20 to 22, a first protection layer 230 and a first filling layer 240 may be sequentially formed on bottoms and sidewalls of the first openings H1 expanded in the third direction D3 and upper surfaces of the line structures.

The first protection layer 230 may include an insulating nitride, for example, silicon nitride. The first filling layer 240 may include, for example, silicon oxycarbide, silicon oxide, etc.

Subsequently, a planarization process may be performed on an upper portion of the first protection layer 230 and an upper portion of the first filling layer 240 until the upper surfaces of the line structures are exposed. Accordingly, the first protection layer 230 may be separated into a plurality of portions extending in the first direction D1 and spaced apart from each other in the second direction D2, and the first filling layer 240 may be separated into a plurality of portions extending in the first direction D1 and spaced apart from each other in the second direction D2.

The planarization process may be performed, for example, by a chemical mechanical polishing (CMP) process and/or an etch-back process.

Referring to FIGS. 23 to 25, a second conductive layer 260 may be formed on the upper surfaces of the line structures, an upper surface of the first protection layer 230, and an upper surface of the first filling layer 240.

The second conductive layer 260 may include a metal, for example, tungsten (W), platinum (Pt), palladium (Pd), rhodium (Rh), ruthenium (Ru), iridium (Ir), copper (Cu), aluminum (Al), titanium (Ti), tantalum (Ta), etc., or a metal nitride, for example, titanium nitride (TiNₓ), tungsten nitride (WNₓ), tantalum nitride (TaNₓ), etc.

In an example embodiment, the second conductive layer 260 may include a metal layer and a barrier layer covering a lower surface of the metal layer. The metal layer may include, for example, a metal, for example, tungsten (W), platinum (Pt), palladium (Pd), rhodium (Rh), ruthenium (Ru), iridium (Ir), copper (Cu), aluminum (Al), titanium (Ti), tantalum (Ta), etc., and the barrier layer may include a metal nitride, for example, titanium nitride (TiNₓ), tungsten nitride (WNₓ), tantalum nitride (TaNₓ), etc.

Referring to FIGS. 26 to 28, an etching process may be performed on the second conductive layer 260, the second electrode lines 212, the second barrier lines 202, the selection lines 192, the first barrier lines 182, the third barrier lines 222, the upper portion of the first protection layer 230, and the upper portion of the first filling layer 240 to form second openings H2 exposing the upper surfaces of the first electrode lines 172. In example embodiments, the second openings H2 may be formed to extend in the second direction D2 and may be spaced apart from each other in the first direction D1.

By the etching process, the second conductive layer 260, the second electrode lines 212, the second barrier lines 202, the selection lines 192, the first barrier lines 182, and the third barrier lines 222 may be separated into a plurality of second conductive lines 265, a plurality of second electrodes 214, a plurality of second barrier patterns 204, a plurality of selection patterns 194, a plurality of first barrier patterns 184, and a plurality of third barrier patterns 224, respectively. Additionally, the first protection layer 230 may be separated into a plurality of portions spaced apart from each other in the first direction D1, and the first filling layer 240 may be separated into a plurality of portions spaced apart from each other in the first direction D1.

In example embodiments, the second conductive lines 265 may be formed to extend in the first direction D1 and may be spaced apart from each other in the second direction D2. In example embodiments, the second electrodes 214 may be formed to be spaced apart from each other in the first and second directions D1 and D2. In example embodiments, the second barrier patterns 204 may be formed to be spaced apart from each other in the first and second directions D1 and D2. In example embodiments, the selection patterns 194 may be formed to be spaced apart from each other in the first and second directions D1 and D2. In example embodiments, the first barrier patterns 184 may be formed to be spaced apart from each other in the first and second directions D1 and D2. In example embodiments, the third barrier patterns 224 may be formed to be spaced apart from each other in the first and second directions D1 and D2.

Meanwhile, a first barrier pattern 184, a selection pattern 194, a second barrier pattern 204, and a second electrode 214 sequentially stacked on the first electrode line 172 may together form each of stack structures. Accordingly, the stack structures may be formed to be spaced apart from each other in the first and second directions D1 and D2.

Referring to FIGS. 29 to 31, a fourth barrier layer 270 may be formed along bottoms and sidewalls of the second openings H2 and sidewalls in the first direction D1 and upper surfaces of the second conductive lines 265.

In example embodiments, the fourth barrier layer 270 may include silicon nitride (SiN). In example embodiments, when the fourth barrier layer 270 is a silicon nitride layer, a thickness of the silicon nitride layer may range from about 10 Å to 20 Å.

In example embodiments, the fourth barrier layer 270 may include a high-k dielectric material, for example, hafnium oxide (HfO₂), zirconium oxide (ZrO₂), aluminum oxide (Al₂O₃), tantalum oxide (Ta₂O₅), titanium oxide (TiO₂), etc.

In example embodiments, the fourth barrier layer 270 may be a cation exchange membrane. The cation exchange membrane may be formed of fluorine-based polymers including Perfluorosulfonic acid (PFSA) series, or hydrocarbon-based polymers including sulfonated polyetheretherketone (SPEEK), sulfonated polysulfone (SPSF), sulfonated polyimide (SPI), etc.

Referring to FIGS. 32 to 34, an anisotropic etching process, for example, may be performed on the fourth barrier layer 270. Accordingly, the fourth barrier layer 270 may be separated into a plurality of fourth barrier lines 272.

In example embodiments, the fourth barrier lines 272 may be formed on edge portions in the first direction D1 of upper surfaces of the first electrodes 174, may extend in the second direction D2 along sidewalls in the first direction D1 of the stack structures, sidewalls in the first direction D1 of the third barrier patterns 224, sidewalls in the first direction D1 of the first protection layer 230, and sidewalls in the first direction D1 of the first filling layer 240, and may be formed to be spaced apart from each other in the first direction D1.

Subsequently, an etching process may be performed on the first electrode lines 172, a lower portion of the first protection layer 230, and a lower portion of the first filling layer 240 through the second openings H2 to expose the upper surfaces of the first conductive lines 140 and the upper surface of the second insulating interlayer 160. Accordingly, the second openings H2 may be expanded in the third direction D3.

By the etching process, each of the first electrode lines 172 may be separated into a plurality of first electrodes 174 spaced apart from each other in the first direction D1. In example embodiments, the first electrodes 174 may be formed to be spaced apart from each other in the first and second directions D1 and D2.

Additionally, by the etching process, the first protection layer 230 may be separated into a plurality of portions spaced apart from each other in the first and second directions D1 and D2, and the first filling layer 240 may be separated into a plurality of portions spaced apart from each other in the first and second directions D1 and D2.

During the etching process, since the sidewalls in the first direction D1 of the stack structures are covered by the fourth barrier lines 272, a width in the first direction D1 of each of the first electrodes 174 may be formed larger than a width in the first direction D1 of each of the stack structures.

In example embodiments, a distance between outer sidewalls in the first direction D1 of the fourth barrier lines 272 formed on opposite sidewalls in the first direction D1 of each of the stack structures may be formed to be substantially the same as the width in the first direction D1 of each of the first electrodes 174.

The first electrode 174, the selection pattern 194, and the second electrode 214 sequentially stacked in the third direction D3 may together form each of the memory cells. The memory cells may be formed to be spaced apart from each other in the first and second directions D1 and D2, and the memory cells may together form a memory cell array.

Additionally, the first barrier patterns 184 covering lower surfaces of the selection patterns 194, the second barrier patterns 204 covering upper surfaces of the selection patterns 194, the third barrier patterns 224 covering sidewalls in the second direction D2 of the selection patterns 194, and the fourth barrier lines 272 covering sidewalls in the first direction D1 of the selection patterns 194 may together form a barrier structure.

Referring back to FIGS. 1 to 4, a second protection layer 280 and a second filling layer 290 may be formed on the bottoms and the sidewalls of the second openings H2, upper surfaces of the fourth barrier lines 272, and the upper surfaces of the second conductive lines 265.

The second protection layer 280 may include an insulating nitride, for example, silicon nitride. The second filling layer 290 may include, for example, silicon oxycarbide, silicon oxide, etc.

Subsequently, a planarization process may be performed on an upper portion of the second protection layer 280 and an upper portion of the second filling layer 290 until the upper surfaces of the second conductive lines 265 are exposed. Accordingly, the second protection layer 280 may be separated into a plurality of portions extending in the second direction D2 and spaced apart from each other in the first direction D1. The second filling layer 290 may be separated into a plurality of portions extending in the second direction D2 and spaced apart from each other in the first direction D1.

The planarization process may be performed, for example, by a chemical mechanical polishing (CMP) process and/or an etch-back process.

In the method of manufacturing the memory device, the first and second barrier layers 180 and 200 respectively covering the upper and lower surfaces of the selection layer 190 may be formed. Subsequently, an etching process may be performed to form selection lines 192 each extending in the first direction D1, and a third barrier layer 220 covering the sidewalls in the second direction D2 of the selection lines 192 may be formed. Subsequently, an etching process may be performed on the selection lines 192 to form the selection patterns 194 spaced apart from each other in the first and second directions D1 and D2, and the fourth barrier layers 270 covering the sidewalls in the first direction D1 of the selection patterns 194 may be formed. Accordingly, each of the selection patterns 194 may be formed to be surrounded by the barrier structure, which may prevent escape of components of the selection patterns 194, for example, selenium anions. Thus, reliability of the memory device may be improved.

Additionally, the etching process may be performed on the first electrode layer 170 after forming the third barrier lines 222, and the etching process may be performed on the first electrode lines 172 after forming the fourth barrier lines 272. Accordingly, the sidewalls of the first electrodes 174 may be spaced apart from the sidewalls of the selection patterns 194 in the horizontal direction. This configuration may reduce migration or escape of components from the selection patterns 194 along the sidewalls of the selection patterns 194 and the first electrodes 174, thereby improving the reliability of the memory device.

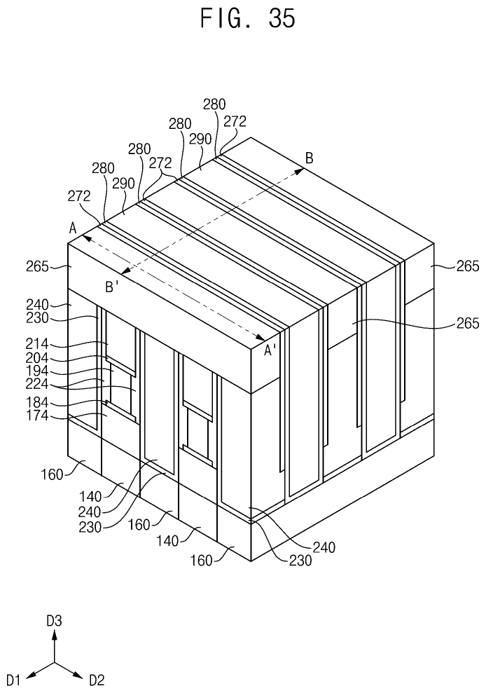

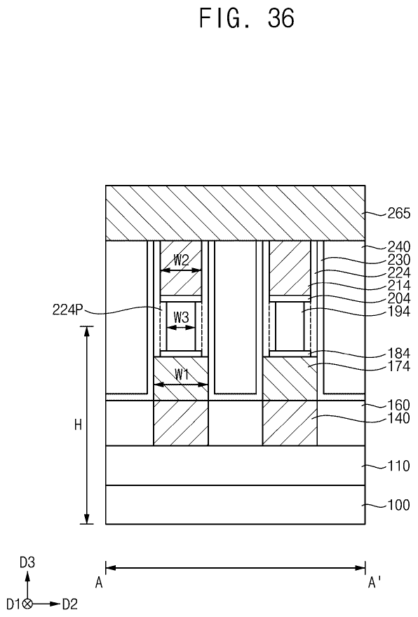

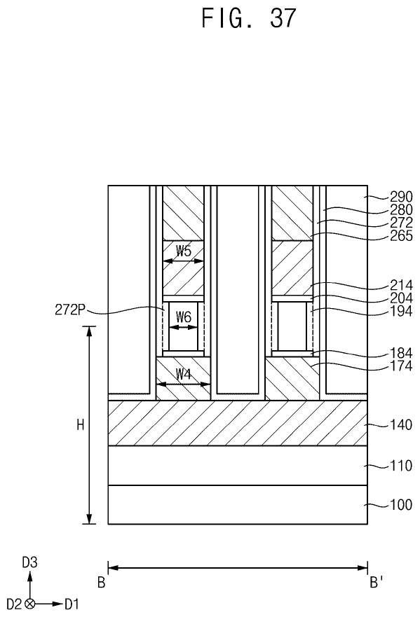

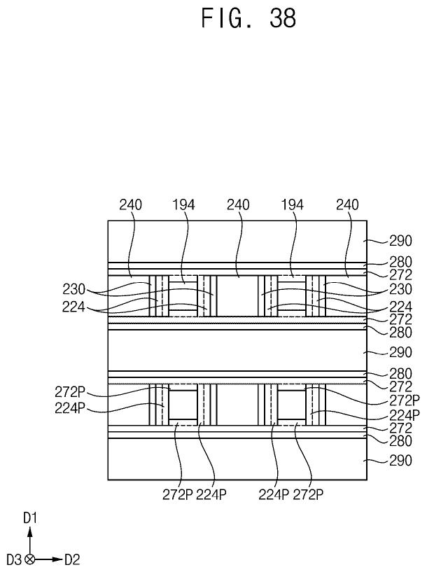

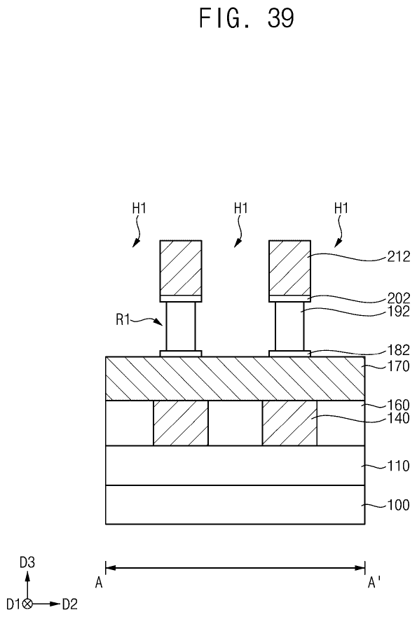

FIGS. 35 to 38 are a perspective view, vertical cross-sectional views, and a horizontal cross-sectional view illustrating a memory device according to example embodiments, corresponding to FIGS. 1 to 4, respectively.

The memory devices may be substantially the same or similar to those described with reference to FIGS. 1 to 4, except for the shape of the selection patterns 194, the shape of the third barrier patterns 224, and the shape of the fourth barrier lines 272, and thus, repeated explanations are omitted herein.

Referring to FIGS. 35 to 38, the sidewalls in the first and second directions D1 and D2 of the selection pattern 194 may be disposed inward compared to the sidewalls in the first and second directions D1 and D2 of the first barrier pattern 184 and the sidewalls in the first and second directions D1 and D2 of the second barrier pattern 204.

In example embodiments, the first width W1 in the second direction D2 of the first electrode 174 may be greater than the second width W2 in the second direction D2 of the second electrode 214. In example embodiments, the third width W3 in the second direction D2 of the selection pattern 194 may be smaller than the second width W2 in the second direction D2 of the second electrode 214.

In example embodiments, the fourth width W4 in the first direction D1 of the first electrode 174 may be greater than the fifth width W5 in the first direction D1 of the second electrode 214. In example embodiments, the sixth width W6 in the first direction D1 of the selection pattern 194 may be smaller than the fifth width W5 in the first direction D1 of the second electrode 214.

In example embodiments, the first area of a horizontal cross-section of the first electrode 174 may be greater than the second area of a horizontal cross-section of the second electrode 214. In example embodiments, the third area of a horizontal cross-section of the selection pattern 194 may be smaller than the second area of a horizontal cross-section of the second electrode 214.

In example embodiments, each of the third barrier patterns 224 may further include a first protrusion 224P that overlaps with the first and second barrier patterns 184 and 204 and the second electrodes 214 in the third direction D3 at a height corresponding to the selection pattern 194.

In example embodiments, each of the fourth barrier lines 272 may further include second protrusions 272P that overlap with the first and second barrier patterns 184 and 204 and the second electrodes 214 in the third direction D3 at a height corresponding to the selection patterns 194.

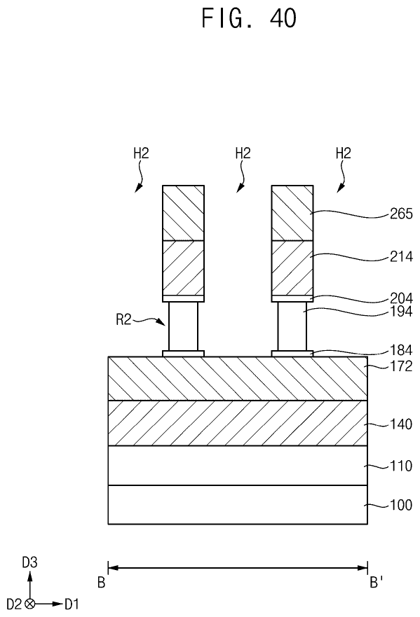

FIGS. 39 and 40 are vertical cross-sectional views taken along lines A-A′ and B-B′ of corresponding perspective views, respectively, illustrating a memory device according to example embodiments. The method of manufacturing the memory device includes processes that are substantially the same or similar to those described with reference to FIGS. 5 to 34 and FIGS. 1 to 4, and thus, repeated explanations are omitted herein.

Referring to FIG. 39, processes that are substantially the same or similar to those described with reference to FIGS. 5 to 13 may be performed.

First recesses R1 may be formed on opposite sidewalls in the second direction D2 of each of the selection lines 192.

In example embodiments, the first recesses R1 may be formed due to differences in etching selectivity during the processes described with reference to FIGS. 11 to 13. In example embodiments, the first recesses R1 may be formed by performing an etching process to remove side portions in the second direction D2 of the selection lines 192 through the first openings H1.

Referring to FIG. 40, processes that are substantially the same or similar to those described with reference to FIGS. 14 to 28 may be performed.

Second recesses R2 may be formed on opposite sidewalls in the first direction D1 of each of the selection patterns 194.

In example embodiments, the second recesses R2 may be formed due to differences in etching selectivity during the processes described with reference to FIGS. 26 to 28. In example embodiments, the second recesses R2 may be formed by performing an etching process to remove side portions in the first direction D1 of the selection patterns 194 through the second openings H2.

Subsequently, the manufacturing of the memory device may be completed by performing processes that are substantially the same or similar to those described with reference to FIGS. 29 to 34, and FIGS. 1 to 4.

While the inventive concept has been shown and described with reference to exemplary embodiments thereof, it will be apparent to those of ordinary skill in the art that various modifications in form and details may be made thereto without departing from the spirit and scope of the inventive concept as set forth by the following claims.

What is claimed is:

1. A memory device comprising:
a first conductive line on a substrate and extending in a first direction substantially parallel to an upper surface of the substrate;
a second conductive line on the first conductive line and extending in a second direction that is substantially parallel to the upper surface of the substrate and crosses the first direction;
a memory cell including a first electrode, a selection pattern including an Ovonic Threshold Switch (OTS) material, and a second electrode that are sequentially stacked between an upper surface of the first conductive line and a lower surface of the second conductive line; and
a barrier structure covering an upper surface, a lower surface, opposite sidewalls in the first direction and opposite sidewalls in the second direction of the selection pattern.

2. The memory device of claim 1, wherein the barrier structure includes silicon nitride.

3. The memory device of claim 2, wherein the barrier structure has a thickness in a range of 10 Å to 20 Å.

4. The memory device of claim 1, wherein the barrier structure includes a high-k dielectric material.

5. The memory device of claim 1, wherein the barrier structure includes a cation exchange membrane.

6. The memory device of claim 1, wherein a first distance between outer sidewalls in the first direction of the barrier structure is substantially equal to a first width in the first direction of the first electrode, and a second distance between outer sidewalls in the second direction of the barrier structure is substantially equal to a second width in the second direction of the first electrode.

7. A memory device comprising:
a first conductive line on a substrate and extending in a first direction substantially parallel to an upper surface of the substrate;
a second conductive line on the first conductive line and extending in a second direction that is substantially parallel to the upper surface of the substrate and crosses the first direction;
a first electrode on an upper surface of the first conductive line in a region where the first and second conductive lines overlap each other in a third direction substantially perpendicular to the upper surface of the substrate;
a first barrier pattern on the first electrode and including silicon nitride or a high-k dielectric material;
a selection pattern on the first barrier pattern;
a second barrier pattern on the selection pattern and including silicon nitride or a high-k dielectric material;
a second electrode on the second barrier pattern;
third barrier patterns respectively covering opposite sidewalls in the second direction of the selection pattern; and
barrier lines respectively covering opposite sidewalls in the first direction of the selection pattern.

8. The memory device of claim 7, wherein the high-k dielectric material is selected from a group consisting of hafnium oxide, zirconium oxide, aluminum oxide, tantalum oxide, and titanium oxide.

9. The memory device of claim 7, wherein the selection pattern is disposed in a space defined by the first to third barrier patterns and the barrier lines.

10. The memory device of claim 7, wherein the first electrode has a first width in the second direction, the second electrode has a second width in the second direction, and the first width is greater than the second width, and
wherein the first electrode has a third width in the first direction, the second electrode has a fourth width in the first direction, and the third width is greater than the fourth width.

11. The memory device of claim 10, wherein the selection pattern has a fifth width in the second direction, and the fifth width is smaller than the second width, and
wherein the selection pattern has a sixth width in the first direction, and the sixth width is smaller than the fourth width.

12. The memory device of claim 11, wherein the third barrier pattern includes a first protrusion that overlaps with the second electrode in the third direction and protrudes in the second direction, and
the barrier line includes a second protrusion that overlaps with the second electrode in the third direction and protrudes in the first direction.

13. The memory device of claim 7, wherein a first distance between outer sidewalls in the second direction of the third barrier patterns is substantially equal to a first width in the second direction of the first electrode, and a second distance between outer sidewalls in the first direction of the barrier lines is substantially equal to a second width in the first direction of the first electrode.

14. A memory device comprising:
first conductive lines disposed on a substrate, each extending in a first direction substantially parallel to an upper surface of the substrate, and spaced apart from each other in a second direction that is substantially parallel to the upper surface of the substrate and crosses the first direction;
second conductive lines disposed on the first conductive lines, each extending in the second direction, and spaced apart from each other in the first direction;
first electrodes disposed on upper surfaces of the first conductive lines in regions where the first and second conductive lines overlap each other in a third direction substantially perpendicular to the upper surface of the substrate, respectively;
stack structures disposed on the first electrodes, respectively, each of the stack structures including:
a first barrier pattern;
a selection pattern disposed on the first barrier pattern;
a second barrier pattern disposed on the selection pattern; and
a second electrode disposed on the second barrier pattern;
third barrier patterns covering sidewalls in the second direction of the stack structures; and
barrier lines extending in the second direction and covering sidewalls in the first direction of the stack structures disposed along the second direction,
wherein each of the third barrier patterns covers an edge portion in the second direction of an upper surface of each of the first electrodes, and each of the barrier lines covers edge portions in the first direction of upper surfaces of the first electrodes that are disposed along the second direction.

15. The memory device of claim 14, wherein each of the first to third barrier patterns and each of the barrier lines includes silicon nitride, a high-k dielectric material, or a cation exchange membrane.

16. The memory device of claim 14, further comprising:
a first filling structure including a first protection layer and a first filling layer, the first protection layer covering sidewalls in the second direction of the first electrodes and outer sidewalls in the second direction of the third barrier patterns, and the first filling layer filling a remaining space between the stack structures neighboring each other in the second direction; and
a second filling structure including a second protection layer and a second filling layer, the second protection layer covering sidewalls in the first direction of the first electrodes and outer sidewalls in the first direction of the barrier lines, and the second filling layer filling a remaining space between the stack structures neighboring each other in the first direction.

17. The memory device of claim 16, wherein a lower surface of the first filling structure is lower than lower surfaces of the third barrier patterns, and a lower surface of the second filling structure is lower than lower surfaces of the barrier lines.

18. The memory device of claim 14, wherein each of the first electrodes has a first width in the second direction, the second electrode has a second width in the second direction, and the first width is greater than the second width, and
wherein each of the first electrodes has a third width in the first direction, the second electrode has a fourth width in the first direction, and the third width is greater than the fourth width.

19. The memory device of claim 18, wherein the selection pattern has a fifth width in the second direction, and the fifth width is smaller than the second width, and
wherein the selection pattern has a sixth width in the first direction, and the sixth width is smaller than the fourth width.

20. The memory device of claim 19, wherein each of the third barrier patterns includes a first protrusion that overlaps in the third direction with the second electrode included in each of the stack structures and protrudes in the second direction, and
each of the barrier lines includes a second protrusion that overlaps in the third direction with the second electrode included in each of the stack structures disposed along the second direction and protrudes in the first direction.
